(19) United States
(12) Patent Application Publication
(10) Pub. No.: US 2007/0291526 A1
(43) Pub. Date: Dec. 20, 2007

(54) Structure for a non-volatile memory device

(75) Inventors: Tzyh-Cheang Lee, Hsinchu City (TW); Fu-Liang Yang, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/453,357

(22) Filed: Jun. 15, 2006

(51) Int. Cl. G11C 17/00

(52) U.S. Cl. 365/104

(57) ABSTRACT

System for a memory device. An electronic device includes a non-volatile memory array. The non-volatile memory array includes a first transistor and a second transistor. The first and second transistors have a shared doped region. A first word line is formed along a first axis. The first word line includes a first gate electrode for the first transistor and a second gate electrode for the second transistor. The non-volatile memory array includes a bit line formed along a second axis. The first axis is perpendicular to the second axis. The bit line is electrically connected to the shared doped region.

### TECHNICAL FIELD

The present invention generally relates to semiconductor devices. In one aspect, it relates more particularly to a system and method for a non-volatile memory device. More specifically, one aspect of the present invention relates to Silicon-Oxide-Nitride-Oxide-Silicon (SONOS) transistors.

### BACKGROUND

A non-volatile memory (NVM) has storage cells, which number in the millions or billions. Each storage cell includes a transistor that stores 2 bits. A popular NVM design includes SiN storage film below the poly gate, a buried bitline, and the use of virtual ground technology. Using this popular NVM design, NVMs can be manufactured cost effectively. However, the above mentioned popular NVM design has limitations. A primary limitation of the design is lack of scalability. The design does not scale down, and cannot be used with ever decreasing geometry sizes. As semiconductor geometry sizes continue to shrink, the channel length of each transistor in the memory array shrinks, presenting challenges. For example, because the channel lengths shrink, the distance separating the two electric charges in each cell also shrinks. Shrinking the distance between the two electric charges may result in reduced reliability, and memory failure.

To solve the problem of scalability, sidewall SONOS technology may be used. The terms “SONOS”, “sidewall SONOS,” and “SONOS transistor” are used in the art to generally describe a non-volatile transistor structure. The terms “SONOS”, “sidewall SONOS,” and “SONOS transistor” are used herein to generically describe a non-volatile SONOS-type transistor which may or may not have a silicon-oxide-nitride-oxide-silicon structure oriented horizontally. A “SONOS transistor” or a “SONOS sidewall transistor” may include part or all of a generic SONOS structure, and may be either horizontally or vertically oriented. For example, a “SONOS transistor” in one embodiment of the present invention may have a horizontally oriented nitride-oxide-silicon-oxide-nitride structure.

Despite the amenability of SONOS technology to smaller feature sizes, known SONOS memories lack a dense design and are not compact. One known layout has a wide isolation region separating the bitline of sidewall SONOS transistors. However, the wide isolation region increases the size of the memory array, thus increasing the cost of the chip and reducing profit. A compact memory design is critical to saving costly wafer area and to achieving the small memory sizes required by portable electronics, such as cell phones, personal digital assistants, laptops, and digital cameras, for example.

### SUMMARY OF THE INVENTION

The problems and needs outlined above may be addressed by embodiments of the present invention. In accordance with one aspect of the present invention, a method of manufacturing a semiconductor device is described. This method includes the following steps described in this paragraph, and the order of steps may vary, if not otherwise stated. The method includes the formation of a gate dielectric layer over a substrate. A gate electrode layer is formed over the gate dielectric layer. Portions of the gate electrode layer and the gate dielectric layer are patterned and removed to form substantially straight first and second gate stack rows along a first direction. A first pitch separates the first and second gate stack rows. A tunneling oxide is formed over the gate stack rows and over the substrate. A spacer material is formed over the tunneling oxide. Portions of the tunneling oxide and the spacer material are removed to form spacers on oppositely adjacent sides of each gate stack row. The spacers are separated from the gate stack row by the tunneling oxide. A dopant material is implanted into the silicon substrate on oppositely adjacent sides of the gate stack rows to form first, second, third, and fourth transistors. The first, second, third, and fourth transistors each have a first and second doped region. The first doped region of the first transistor, the first doped region of the second transistor, the first doped region of the third transistor, and the first doped region of the fourth transistor are each part of a shared doped region. An interlayer dielectric material is formed over the transistors. A contact is formed in the interlayer dielectric material. The contact is electrically connected to the shared doped region. A write line is formed over the interlayer dielectric material, directly over the contact, and along a second direction. The second direction is substantially perpendicular to the first direction.

In accordance with another illustrative embodiment of the present invention, a method of manufacturing a semiconductor device is described. A gate dielectric layer is formed over a substrate. A gate electrode layer is formed over the gate dielectric layer. Portions of the gate electrode layer and the gate dielectric layer are patterned and removed to form a substantially straight first gate stack row along a first axis and to form a substantially straight second gate stack row substantially parallel to the first gate stack row. A first pitch separates the first and second gate stack rows. A tunneling oxide layer is formed over the gate stack rows and over the substrate. A spacer material is formed over the tunneling oxide. Portions of the tunneling oxide and the spacer material are removed to form spacers on oppositely adjacent sides of each gate stack row. The spacers are separated from the gate stack row by the tunneling oxide. A dopant material is implanted into the silicon substrate on oppositely adjacent sides of the gate stack rows to form first and second SONOS transistors of a memory array. The first and second SONOS transistors each have a first and second doped region. The first doped region of the first transistor and the first doped region of the second transistor are each part of a shared doped region. An interlayer dielectric material is formed over the transistors. A contact is formed in the interlayer dielectric material. The contact is electrically connected to the shared doped region. A write line is formed over the interlayer dielectric material, directly over the contact, and along a second direction. The direction is substantially perpendicular to the first direction.

In accordance with another illustrative embodiment of the present invention, an electronic device is described. The electronic device includes a non-volatile memory array. The non-volatile memory array includes a first SONOS transistor and a second SONOS transistor. The first and second SONOS transistors have a shared doped region. A first word line is formed along a first axis. The first word line includes a first gate electrode for the first SONOS transistor and a second gate electrode for the second SONOS transistor. The non-volatile memory array includes a bit line formed along a second axis. The first axis is perpendicular to the second axis. The bit line is electrically connected to the shared doped region.

In accordance with another illustrative embodiment of the present invention, an electronic device is described. The electronic device includes a non-volatile memory array. The non-volatile memory array includes a first transistor, a second transistor, a third transistor, a fourth transistor, and a shared doped region for the first, second, third, and fourth transistors. The non-volatile memory array also includes a first word line formed along a first axis. The first word line includes a first gate electrode for the first transistor and a second gate electrode for the second transistor. A second word line is substantially parallel to the first word line and separated from the first word line by a first cell pitch. The second word line includes a third gate electrode of the third transistor and a fourth gate electrode of the fourth transistor. The non-volatile memory array further includes a bit line formed along a second axis. The first axis is perpendicular to the second axis, and the bit line is electrically connected to the shared doped region. Preferably the first, second, third, and fourth transistors are non-volatile transistors. As one example, the first, second, third, and fourth transistors may be sidewall SONOS transistors.

In accordance with another illustrative embodiment of the present invention, a memory array is described. The memory array includes a first SONOS transistor, a second SONOS transistor, a third SONOS transistor, and a fourth SONOS transistor, and a shared doped region for the first, second, third, and fourth SONOS transistors. The memory array includes a first word line formed along a first axis. The first word line includes a first gate electrode for the first SONOS transistor and a second gate electrode for the second SONOS transistor. The memory array also includes a second word line substantially parallel to the first word line and separated from the first word line by a first cell pitch. The second word line includes a third gate electrode of the third SONOS transistor and a fourth gate electrode of the fourth SONOS transistor. The memory array further includes a bit line formed along a second axis. The first axis is perpendicular to the second axis. The bit line is electrically connected to the shared doped region. A gate length for each of the transistors is about 130 nm or less.

The foregoing has outlined rather broadly features of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The following is a brief description of the drawings, which illustrate exemplary embodiments of the present invention and in which:

FIGS. 1A provides a simplified three-dimension view of a wafer region in accordance with a first illustrative embodiment of the present invention;

FIGS. 1B, 1C, 2A, and 2B provide simplified cross-section views of the wafer region in accordance with the first illustrative embodiment of the present invention;

FIG. 2C provides a simplified three-dimension view of the wafer region in accordance with the first illustrative embodiment of the present invention;

FIGS. 3A provides a simplified three-dimension view of a wafer region in accordance with the first illustrative embodiment of the present invention;

FIG. 3B provides a simplified cross-section view of the wafer region in accordance with the first illustrative embodiment of the present invention;

FIG. 3C provides a simplified plan view of the wafer region in accordance with the first illustrative embodiment of the present invention;

FIG. 4 provides a simplified three-dimension view of the wafer region in accordance with the first illustrative embodiment of the present invention;

FIG. 5A provides a simplified plan view of the wafer region in accordance with the first illustrative embodiment of the present invention;

FIG. 5B provides a simplified cross-section view of the wafer region in accordance with the first illustrative embodiment of the present invention;

FIG. 5C provides a simplified plan view of the unit cell in accordance with the first illustrative embodiment of the present invention;

FIG. 5D provides a simplified cross-section view of the wafer region in accordance with the first illustrative embodiment of the present invention;

FIG. 6A provides a simplified plan view of the non-volatile memory of the first illustrative embodiment of the present invention; and

FIG. 6B provides a simplified plan view of the wireless communications chip of the first illustrative embodiment of the present invention.

### DETAILED DESCRIPTION OF ILLUSTRATIVE EMBODIMENTS

Referring now to the drawings, wherein like reference numbers are used herein to designate like or similar elements throughout the various views, illustrative embodiments of the present invention are shown and described. The figures are not necessarily drawn to scale, and in some instances the drawings have been exaggerated and/or simplified in places for illustrative purposes only. One of ordinary skill in the art will appreciate the many possible applications and variations of the present invention based on the following illustrative embodiments of the present invention.

An embodiment of present invention is preferably a non-volatile transistor. A first illustrative embodiment of the present invention provides a method of manufacturing a wireless communications chip. The wireless communications chip includes non-volatile transistor application in the form of a sidewall SONOS transistor, for example. The terms “SONOS”, “sidewall SONOS” and “SONOS transistor” are used in the art to generally describe a non-volatile transistor structure. The terms “SONOS”, “sidewall SONOS” and “SONOS transistor” are used herein to generically describe a non-volatile SONOS-type transistor which may or may not have a vertically oriented silicon-oxide-nitride-oxide-silicon structure. A “SONOS transistor” may include part or all of a SONOS structure, either horizontally or vertically oriented. For example, a “SONOS transistor” in one embodiment of the present invention may have a horizontal nitride-oxide-silicon-oxide-nitride structure.

The wireless communications chip is manufactured in a 60 nanometer (nm) semiconductor manufacturing process on a wafer that is about 300 millimeters (mm) in diameter. However, the present invention is not limited to a manufacturing technology or wafer size. Other illustrative embodiments of the present invention include manufacturing processes at technology nodes including 0.180 um, 0.150 um, 0.130 um, 90 nm, 45 nm, and 30 nm, for example. Illustrative embodiments of the present invention also include wafer sizes of 100 mm, 200 mm, 300 mm, and 450 nm, for example.

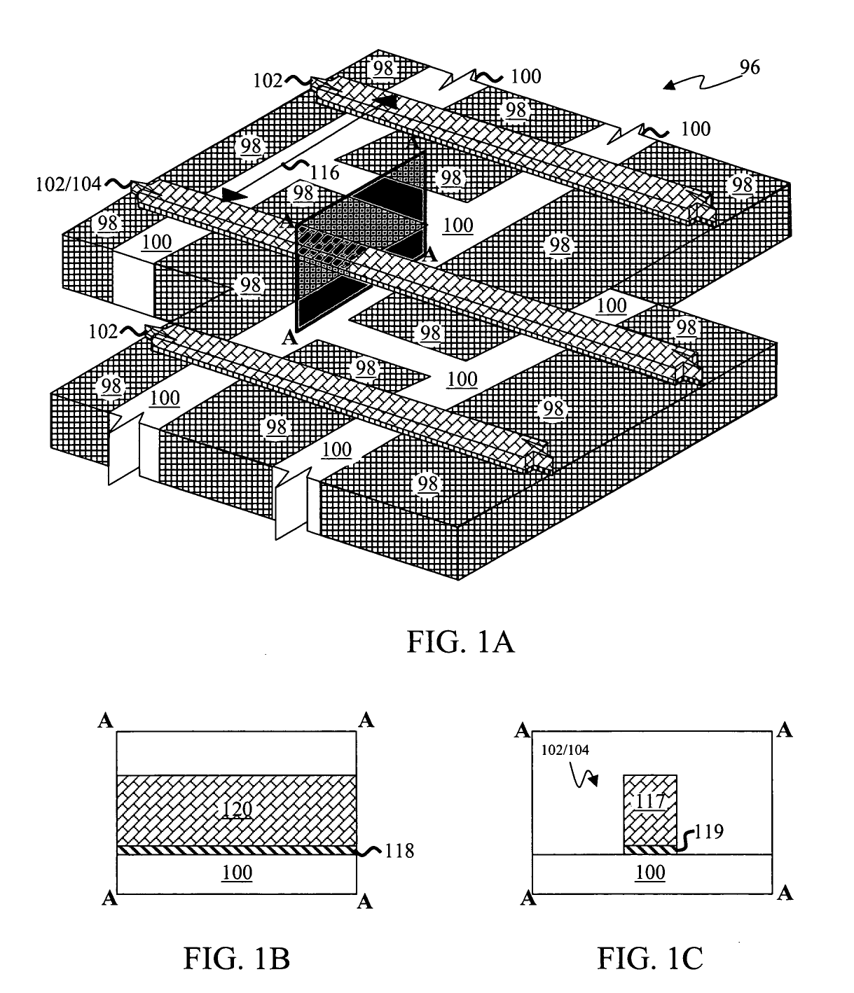

FIG. 1A is a three dimensional image showing a region 96 of the wafer. Shallow trench isolation (STI) 98 has been formed in the wafer substrate 100. In FIG. 1 A, gate stack rows 102 have been formed over a p-type substrate 100 and over the STI 98. The gate stack rows 102 are substantially parallel to each other and separated by a row pitch 116. The gate stack rows 102 preferably function as word lines during device operation. The formation of the gate stack row 104 is shown in FIGS. 1B and 1C. FIGS. 1B and 1C show a cross section of the gate stack row 104 along the plane A-A-A-A in FIG. IA.

FIG. 1B shows the gate dielectric layer 118 of the gate stack row 104 grown directly over the substrate 100. The gate dielectric layer 118 is preferably an oxide material, such as a thin oxide material, for example. A gate electrode layer 120 is formed over the gate dielectric layer 118. The gate electrode layer 120 is preferably a polysilicon material, but may be any conductive material suitable for functioning as a transistor gate, such as a metal material for example. In FIG. 1C, portions of the gate dielectric layer 118 and the gate electrode layer 120 have been patterned and removed to form a gate electrode 117 over a gate dielectric 119.

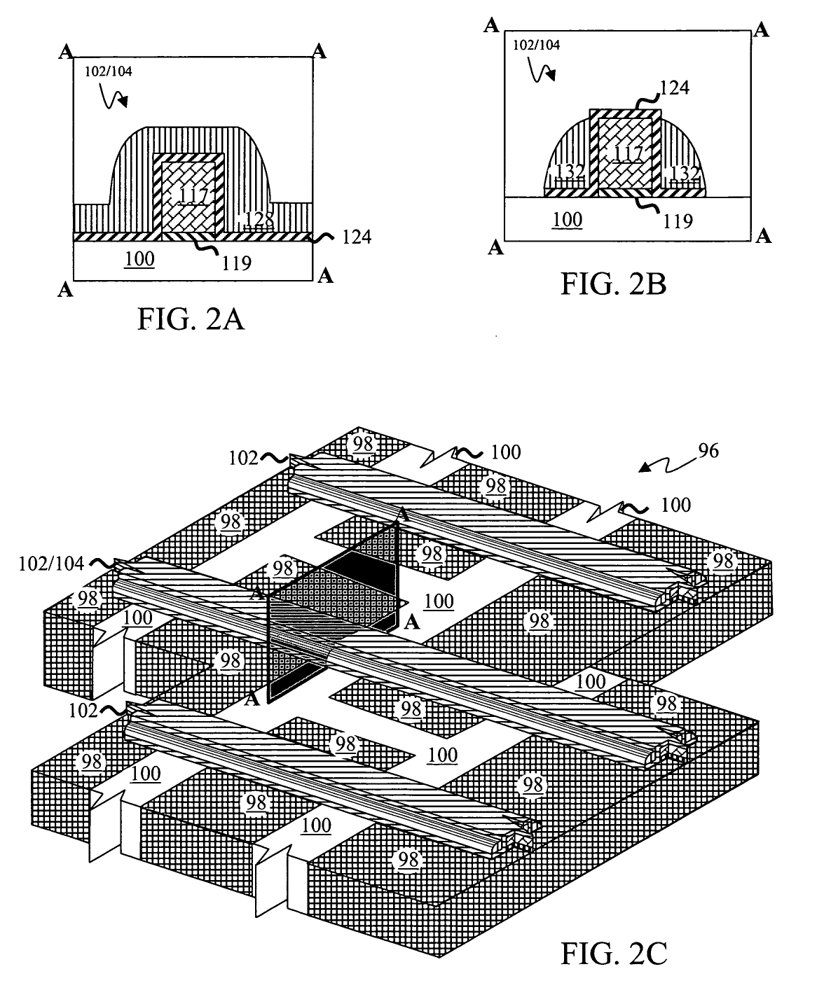

FIG. 2A shows a cross section of the gate stack row 104 after further processing. In FIG. 2A, a tunneling oxide 124 has been formed over the substrate 100, including over the gate stack row 104. A spacer material 128 is formed over the tunneling oxide 124. The spacer material 128 is a silicon nitride material in this embodiment. However, in other illustrative embodiments the spacer material 128 is any suitable material having charge trapping properties, including any nitride material, for example.

FIG. 2B is a cross-sectional view of the gate stack row 104 after the removal of portions of the tunneling oxide 124 and portions of the spacer material 128 have formed spacers 132. The spacers 132 are on oppositely adjacent sides of the gate stack row 104, and are separated from the substrate 100 by the tunneling oxide 124. The spacers 132 are separated from the gate electrode 117 by the tunneling oxide 124. FIG. 2C shows a three-dimensional view of the gate stack rows 102, 104, 108 after formation of the spacers 132. The plane A-A-A-A in FIG. 2C that passes through the gate stack row 104 corresponds to the cross sectional view of the gate stack row 104 in FIG. 2B.

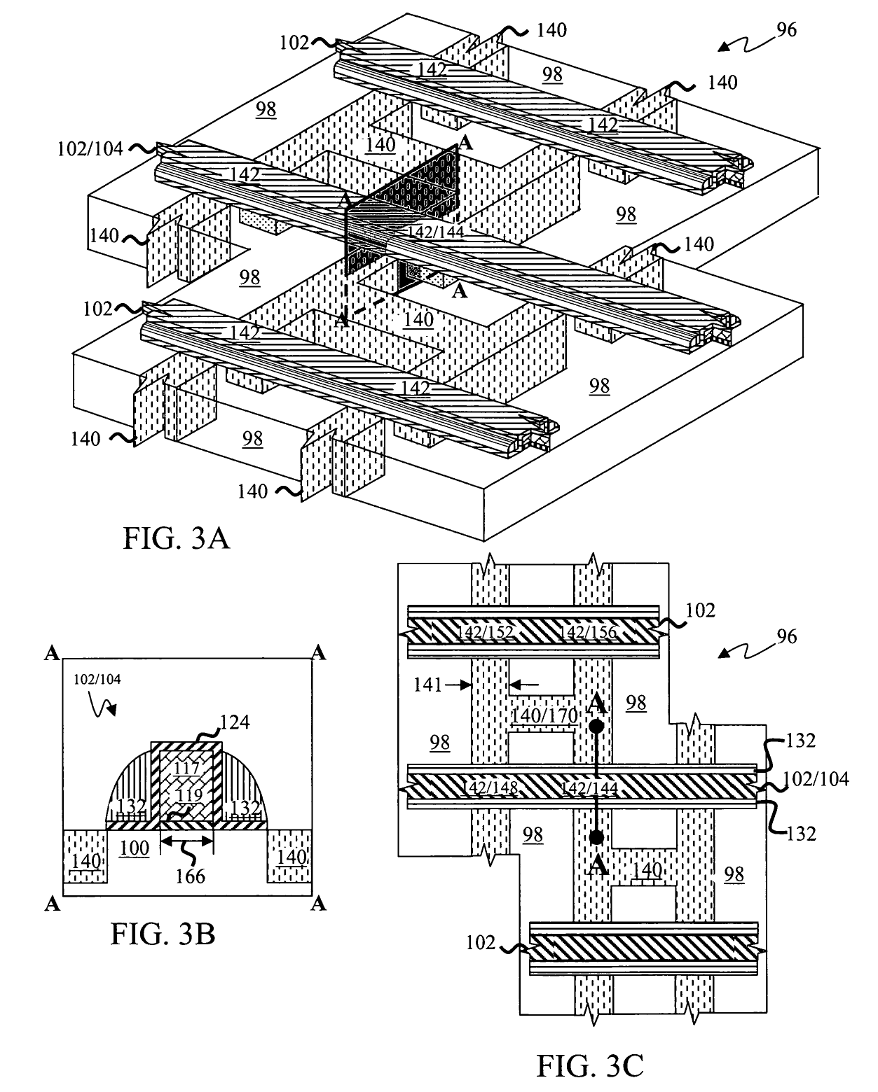

FIG. 3A is an illustration in three dimensions of the wafer region 96 after an n-type dopant material has been implanted into the silicon substrate 100 to form doped regions, 140. The doped regions 140 and the gate stack rows 102 form silicon-oxide-nitride-oxide-silicon (SONOS) transistors 142. The plane A-A-A-A in FIG. 3A cuts through the SONOS transistor 144.

FIG. 3B is a cross-sectional representation of the SONOS transistor 144 along the plane A-A-A-A in FIG. 3A. FIG. 3B shows the doped regions 140 on oppositely adjacent sides of the gate stack row 104. The doped regions 140 in the substrate 100 function as source and drain regions during operation. Each spacer 132 in the SONOS transistor 144 stores a separate electric charge representing one binary digit (a.k.a. a bit). Thus, the SONOS transistor 144 stores two bits. Channel hot-electron injection (CHE) or Fowler-Nordheim (FN) tunneling may be used to program the SONOS transistor 144. Erasing is performed by 2-sided hot-hole injection resulting from band-to-band tunneling or FN tunneling. FIG. 3B shows the gate length 166 of the SONOS transistor 144. The gate length is preferably about 65 nm. Although it is preferable to use the minimum gate length possible, any gate length may be used, such as 180 nm, 130 nm, 90 nm, 45 nm, and 30 nm, for example. In other illustrative embodiments, the SONOS transistors 142 (see e.g., FIG. 3A) all have the same gate length 166 as the SONOS transistor 144.

FIG. 3C is a plan view of the wafer region 96 at the same stage shown in the three dimensional image of FIG. 3A. Note that FIG. 3B is a cross-sectional view of the SONOS transistor 144 along the line A-A in FIG. 3C. Also note that the line A-A in FIG. 3C corresponds to the position of the plane A-A-A-A in FIG. 3A. FIG. 3C shows the gate width 141 of the SONOS transistor 152. The gate width is preferably about 65 nm. Although it is preferable to use the minimum gate width of the manufacturing process, any gate width may be used, such as 180 nm, 130 nm, 90 nm, 45 nm, and 30 nm, for example. The gate widths 141 of the SONOS transistors 142 are all the same in this embodiment. The SONOS transistors 144, 148, 152, 156 share the doped region 170. During operation, the shared doped region 170 may function interchangeably as a source region or a drain region.

FIG. 3C shows that the shared doped region 170 is generally H-shaped. However, in other illustrative embodiments, shared doped regions may have other shapes. For example, shared doped regions in other embodiments may be generally I-shaped, generally N-shaped, generally Z-shaped, or generally X-shaped.

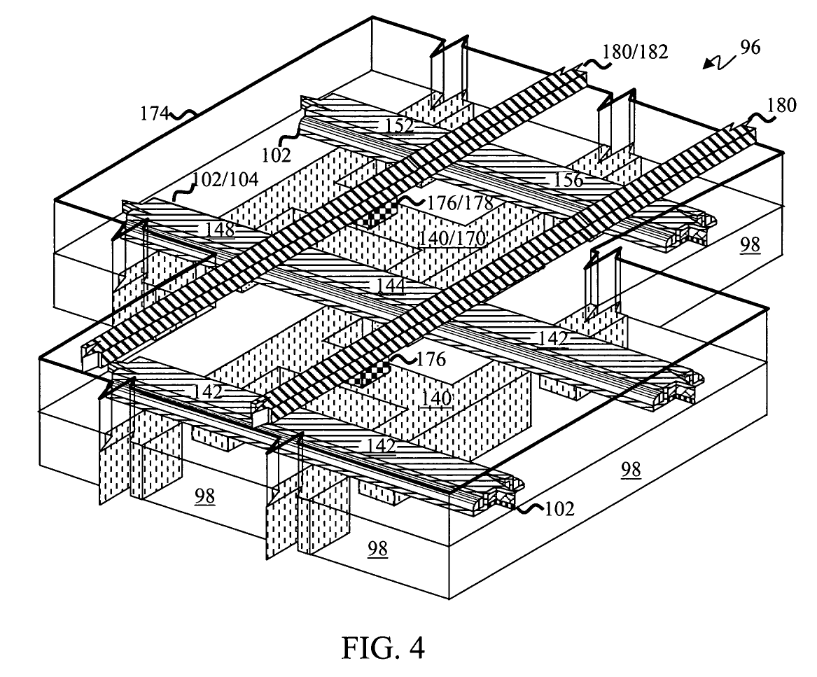

FIG. 4 shows an interlayer dielectric (ILD) 174 formed over the substrate 100. The ILD 174 preferably includes oxide materials and may include multiple layers. The ILD 174 may include a channel stop layer and a low-k dielectric layer, for example. Bit lines 180 are wires that have been formed over the ILD 174. Preferably, the bit lines 180 are substantially aligned with the underlying STI 98. Contacts 176 have been formed in the ILD 174, electrically connecting the bit line wires 180 to shared doped regions 140. The contact 178 formed in the ILD 174 electrically connects the shared doped region 170 to the wire 182. The wire 182 is over the ILD 174, directly over the contact 178, and along a direction perpendicular to the direction of the gate stack row 104. The wire 182 preferably comprises a metal material such as aluminum, tungsten, or copper, for example. The wire 182 functions as a bit line during device operation. The contact 178 electrically connects the transistors 144, 148, 152, 156 to the bit line 182, and is herein also referred to as a shared contact 178.

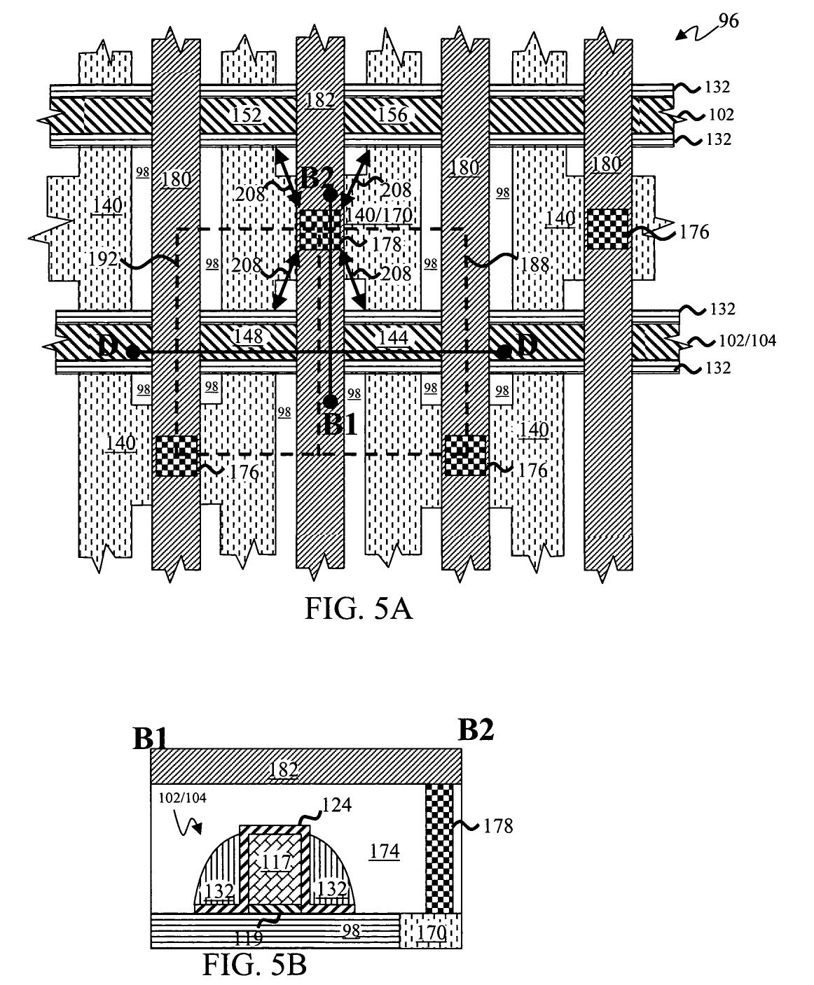

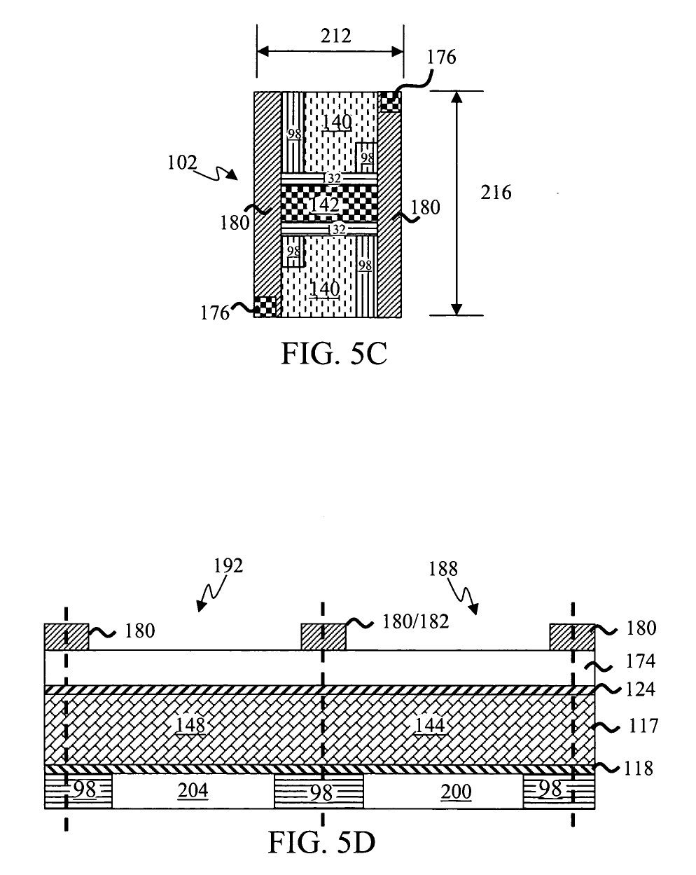

FIG. 5A is a plan view of the wafer region 96 at the same stage shown in the three dimensional image of FIG. 4. The dotted lines in FIG. 5A show the boundaries of two adjacent memory cells 188 and 192. The two adjacent memory cells 188, 192 share the contact 178 and the bit line 182. The bit line 182 is parallel with the underlying STI 98. The SONOS transistor 144 in the memory cell 188 is isolated from the SONOS transistor 148 in the memory cell 192 by the STI 98.

FIG. 5B shows a cross-sectional view along the line B1-B2 of FIG. 5A. FIG. 5B shows the gate stack row 104 over the STI 98. The shared contact 178 in FIG. 5B electrically connects the shared doped region 170 with the overlying bit line 182. The shared contact 178 is isolated from the gate stack row 104 by the ILD 174, as illustrated in FIG. 5B.

FIG. 5C shows a unit cell 202. With combined reference to FIG. 5C and FIG. 5A, it can be seen that the memory cell 192 in FIG. 5A is a copy of the unit cell 202 in FIG. 5C, and has the same orientation. Similarly, the memory cell 188 in FIG. 5A is a horizontally flipped copy of the unit cell 202 in FIG. 5C.

With reference now to FIG. 5C, the unit cell 202 has a cell width 212. The unit cell width 212 is also known as the column pitch or column width. The unit cell 202 also has a unit cell height 216, also known as the row pitch or row height. The unit cell height 216 and unit cell width 212 of the memory cell 192 are significantly smaller than those in known memory designs. The area savings of the unit cell has a multiplied effect on the area savings of the non-volatile memory since it is placed millions or billions of times in a memory array. The area savings translate to a smaller, more dense, non-volatile SONOS memory, and ultimately results in cost savings. Also, the reduced size may translate into higher operating speeds for the memory array.

Referring again to FIG. 5A, line D-D is drawn parallel to the gate stack row 104. FIG. 5D is a cross-sectional view of the gate stack row 104 along the line D-D of FIG. 5A. It can be seen in FIG. 5D that the gate electrode 117 of the gate stack row 104 is the gate electrode 117 of the SONOS transistor 144, and is the gate electrode 117 of the SONOS transistor 148.

In FIG. 5D, the boundaries of the unit cells 188, 192 are shown with dotted lines. The memory cell 188 shares the bit line 182 with the adjacent memory cell 192. FIG. 5D shows the channel region 200 of the SONOS transistor 144 in the memory cell 188, and the channel region 204 of the SONOS transistor 148 in the memory cell 188. The channel regions 200, 204 of the adjacent unit cells 188, 192 are separated by STI 98.

With reference again to FIG. 5A, four distances 208 separate the shared contact 178 from the first SONOS transistor 144, from the second SONOS transistor 148, from the third SONOS transistor 152, and from the fourth SONOS transistor 156. The four distances are about the same, thus the shared contact 178 is equally spaced from the transistors 144, 148, 152, 154. The shared contact 178 need not be centrally positioned in the shared doped region 170. Thus, in other embodiments the shared contact may be spaced unequally from the four transistors that share the contact.

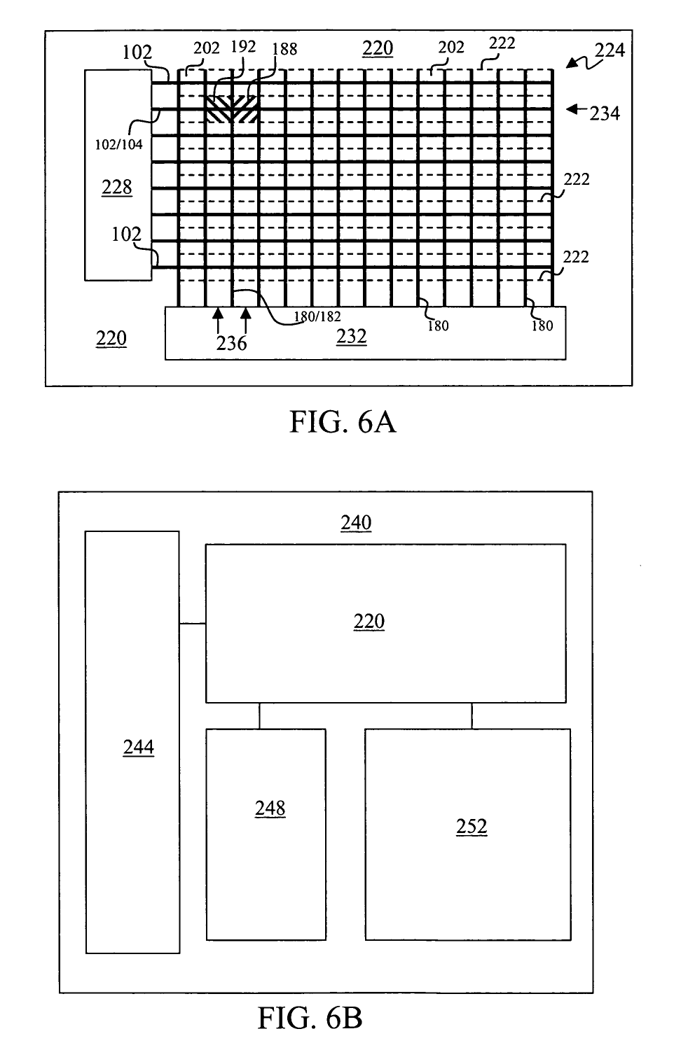

FIG. 6A is a schematic of the non-volatile memory 220. Dotted lines show the boundaries of unit cells 202 in the memory array 220. Bit lines 180 overly the vertical boundaries of the unit cells 202, so that only the horizontal boundaries 222 of the unit cells 220 are visible. The schematic of the memory array 224 represents millions of unit cells in rows and columns. The memory 220 has row control circuitry 228 along the side of the memory array 224 and column control circuitry 232 along the bottom of the memory array 224. Word lines 102 electrically couple row control circuitry 228 to row-aligned unit cells 202 in the memory array 220. Bit lines 180 electrically couple column-aligned unit cells 202 in the memory array 224 to the column control circuitry 232. The memory cells 188 and 192 in the row 234 and adjacent columns 236 of the memory array 220, share the bit line 182. The word line 104 electrically connects the memory cells 188 and 192 to row control circuitry 228.

The non-volatile memory 220 is in a wireless communications chip 240, for example, as shown in FIG. 6B. The non-volatile memory 224 is electrically connected to the custom analog circuitry 244, microprocessor circuitry 248, and digital signal processing circuitry 252. Although this embodiment is shown in a wireless communications chip 240, as an illustrative example, a SONOS transistor array of the present invention may be incorporated into any suitable chip or device.

Although embodiments of the present invention and at least some of its advantages have been described in detail, it should be understood that various changes, substitutions, and alterations can be made herein without departing from the spirit and scope of the invention as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An electronic device comprising a non-volatile memory array, the non-volatile memory array comprising:
a first SONOS transistor and a second SONOS transistor, the first and second SONOS transistors having a shared doped region;
a first word line formed along a first axis, the first word line comprising a first gate electrode for the first SONOS transistor and a second gate electrode for the second SONOS transistor; and
a bit line formed along a second axis, wherein the first axis is perpendicular to the second axis, and wherein the bit line is electrically connected to the shared doped region.

2. The electronic device of claim 1, wherein the shared doped region is a source region.

3. The electronic device of claim 1, wherein the shared doped region is a drain region.

4. The electronic device of claim 1, wherein the word line comprises a polysilicon material.

5. The electronic device of claim 1, wherein the bit line comprises a metal material.

6. The electronic device of claim 1, further comprising:
a third SONOS transistor and a fourth SONOS transistor, wherein each of the third and fourth SONOS transistors has a doped region in the shared doped region; and
a second word line substantially parallel to the first word line and separated from the first word line by a first cell pitch, wherein the second word line comprises a third gate electrode of the third SONOS transistor and a fourth gate electrode of the fourth SONOS transistor.

7. The electronic device of claim 1, wherein a silicon substrate of the memory array is a p-type silicon material and the shared doped region is an n-type silicon material.

8. The electronic device of claim 1, wherein doped regions of the memory array in a plan view comprising the shared doped region of the first and second SONOS transistors, have a shape selected from the group consisting of generally H-shaped, generally I-shaped, generally X-shaped, and combinations thereof.

9. The electronic device of claim 1, wherein the first and second SONOS transistors have a same gate length and a same gate width.

10. The electronic device of claim 9, wherein the gate width and the gate length is selected from the group consisting of 180 nm, 130 nm, 90 nm, 65 nm, 45 nm, 30 nm, and combinations thereof.

11. The electronic device of claim 1, further comprising a shared contact directly over the shared doped region and directly under the bit line.

12. The electronic device of claim 11, wherein the shared contact is equally spaced from the first SONOS transistor and from the second SONOS transistor.

13. The electronic device of claim 6, further comprising a shared contact directly over the shared doped region and directly under the bit line, wherein the shared contact is equally spaced from the first SONOS transistor, from the second SONOS transistor, from the third SONOS transistor, and from the fourth SONOS transistor.

14. The electronic device of claim 1, further comprising an electronic system electrically connected to the non-volatile memory array, wherein the electronic system is selected from the group comprising of a digital signal processor, a microprocessor, analog to digital circuitry, digital to analog circuitry, a transceiver, clock regulating circuitry, power regulation and distribution circuitry, and combinations thereof.

15. An electronic device comprising a non-volatile memory array, the non-volatile memory array comprising:
a first transistor;
a second transistor;
a third transistor;
a fourth transistor;
a shared doped region for the first, second, third, and fourth transistors;
a first word line formed along a first axis, the first word line comprising a first gate electrode for the first transistor and a second gate electrode for the second transistor;
a second word line substantially parallel to the first word line and separated from the first word line by a first cell pitch, wherein the second word line comprises a third gate electrode of the third transistor and a fourth gate electrode of the fourth transistor; and
a bit line formed along a second axis, wherein the first axis is perpendicular to the second axis, and wherein the bit line is electrically connected to the shared doped region.

16. The electronic device of claim 15, further comprising a shared contact directly over the shared doped region and directly under the bit line, wherein the shared contact is equally spaced from the first transistor, from the second transistor, from the third transistor, and from the fourth transistor.

17. The electronic device of claim 15, wherein the first, second, third, and fourth transistors are SONOS transistors.

18. A memory array comprising:
a first SONOS transistor;
a second SONOS transistor;
a third SONOS transistor;
a fourth SONOS transistor;
a shared doped region for the first, second, third, and fourth SONOS transistors;
a first word line formed along a first axis, the first word line comprising a first gate electrode for the first SONOS transistor and a second gate electrode for the second SONOS transistor;
a second word line substantially parallel to the first word line and separated from the first word line by a first cell pitch, wherein the second word line comprises a third gate electrode of the third SONOS transistor and a fourth gate electrode of the fourth SONOS transistor;
a bit line formed along a second axis, wherein the first axis is perpendicular to the second axis, and wherein the bit line is electrically connected to the shared doped region; and
wherein a gate length for each of the transistors is about 130 nm or less.

19. The memory array of claim 18, wherein a gate width for each of the transistors is about 130 nm or less.

20. The memory array of claim 18, further comprising a shared contact directly over the shared doped region and directly under the bit line, wherein the shared contact is equally spaced from the first SONOS transistor, from the second SONOS transistor, from the third SONOS transistor, and from the fourth SONOS transistor.
